(19) United States
(12) Patent Application Publication
(10) Pub. No.: US 2025/0054723 A1
(43) Pub. Date: Feb. 13, 2025

(54) THERMAL CONDITIONING ENCLOSURE FOR A CHARGED PARTICLE INSTRUMENT

(71) Applicant: FEI Company, Hillsboro, OR (US)

(72) Inventors: Rens van Alebeek, Eindhoven (NL); Ronald Lamers, Budel (NL)

(21) Appl. No.: 18/447,812

(22) Filed: Aug. 10, 2023

(51) Int. Cl. H01J 37/16

(52) U.S. Cl. CPC H01J 37/16; H01J 37/26; H01J 2237/002; H01J 2237/2001

(57) ABSTRACT

A charged particle instrument system includes a charged particle instrument, an instrument enclosure, and a thermal conditioning system. The charged particle instrument includes a vacuum enclosure, a charged particle source disposed within the vacuum enclosure, and a magnetic assembly. The charged particle source is configured to produce a beam of charged particles that propagate along an axis and interact with a specimen. The magnetic assembly is disposed within the vacuum enclosure and configured to direct the beam of charged particles toward the specimen. The instrument enclosure defines an interior volume and is configured to receive at least a portion of the charged particle instrument therein. The thermal conditioning system includes a temperature regulator in thermal communication with the charged particle instrument to regulate a temperature of the charged particle instrument and in thermal communication with the instrument enclosure to regulate a temperature of air within the interior volume of the enclosure.

### BACKGROUND

The present disclosure relates to a charged particle instrument, such as a transmission electron microscope (TEM), a scanning transmission electron microscope (STEM), a scanning electron microscope (SEM), and/or a focused ion beam (FIB) instrument, etc. The instrument typically has a specimen chamber in which a specimen is disposed during an operation (e.g., imaging, milling, etc.). Charged particles, such as electrons, are directed at the specimen to perform the operation on the specimen. Performance of the instrument may be affected by the environment in which the instrument is located.

### SUMMARY

Charged particle instruments are highly sensitive, and the performance of the instruments may be affected by aspects of the environment. For example, ambient noise and temperature fluctuations near the instrument may affect the instrument. Most instruments are located within regulated rooms to control temperature and ambient noise. However, it can be expensive to accurately regulate the temperature of an entire room. Accordingly, the present disclosure provides a structure for reducing the effects of temperature fluctuations on charged particle instruments, thereby allowing for relaxation of the room temperature control requirements and/or improving performance of the charged particle instrument.

In one implementation, a charged particle instrument system includes a charged particle instrument, an instrument enclosure, and a thermal conditioning system. The charged particle instrument includes a vacuum enclosure, and a charged particle source disposed within the vacuum enclosure. The charged particle source is configured to produce a beam of charged particles that propagate along an axis and interact with a specimen. The instrument enclosure defines an interior volume and is configured to receive at least a portion of the charged particle instrument therein. The thermal conditioning system includes a temperature regulator in thermal communication with the charged particle instrument to regulate a temperature of the charged particle instrument and in thermal communication with the instrument enclosure to regulate a temperature of air within the interior volume of the instrument enclosure.

In another implementation, a charged particle instrument system includes a charged particle instrument, an instrument enclosure configured to receive at least a portion of the charged particle instrument, and a thermal conditioning system. The charged particle instrument includes a vacuum enclosure, a charged particle source disposed within the vacuum enclosure, a magnetic assembly disposed within the vacuum enclosure, and a controller operably coupled to the charged particle source and to the magnetic assembly. The charged particle source is configured to produce a beam of charged particles that propagate along an axis and interact with a specimen. The magnetic assembly is configured to direct the beam of charged particles toward the specimen. The instrument enclosure includes a plurality of surfaces defining an enclosed interior volume and is configured to decrease an effect of ambient noise on the charged particle instrument. The thermal conditioning system is configured to regulate a temperature of the magnetic assembly and to regulate a temperature of air within the instrument enclosure.

In yet another implementation, an instrument enclosure for use with a charged particle instrument having a thermal conditioning system includes a plurality of surfaces defining an interior volume of the instrument enclosure, the interior volume configured to receive at least a portion of the instrument therein. A heat exchanger is disposed within the interior volume. The heat exchanger is configured to be fluidly coupled to the thermal conditioning system of the charged particle instrument such that the thermal condition system of the charged particle instrument is configured to regulate a temperature of air within the interior volume.

Other aspects of the disclosure will become apparent by consideration of the detailed description and accompanying drawings.

### BRIEF DESCRIPTION OF THE DRAWINGS

FIG. 1 schematically illustrates a longitudinal cross-sectional elevation view of a charged particle microscope in accordance with an implementation of the present disclosure.

FIG. 2 is an enlarged and more detailed view of a magnetic assembly defining a specimen chamber of the charged particle microscope shown in FIG. 1.

FIG. 3 schematically illustrates a charged particle instrument system in accordance with an implementation of the present disclosure.

FIG. 4 illustrates an instrument enclosure in accordance with an implementation of the present disclosure.

FIG. 5A schematically illustrates a thermal circuit in accordance with an implementation of the present disclosure.

FIG. 5B schematically illustrates a thermal circuit in accordance with another implementation of the present disclosure.

FIG. 6A is a graph illustrating instrument enclosure conditioning measurements with heat exchangers off.

FIG. 6B is a graph illustrating instrument enclosure conditioning measurements with heat exchangers on.

FIG. 7 is a graph illustrating modeled transfer functions between room air temperature and enclosure air temperature.

FIG. 8A is a graph illustrating measured temperatures over time with the heat exchangers off.

FIG. 8B is a graph illustrating measured temperatures over time with the heat exchangers on.

### DETAILED DESCRIPTION

Before any implementations of the disclosure are explained in detail, it is to be understood that the disclosure is not limited in its application to the details of construction and the arrangement of components set forth in the following description or illustrated in the following drawings. The disclosure is capable of other implementations and of being practiced or of being carried out in various ways.

Some instruments, such as charged particle instruments, are sensitive to variations in the environment of the instrument. This sensitivity is also known as background drift. One source of background drift is variation in the ambient air temperature, and achieving background drift requirements can be difficult. The sensitivity to ambient air temperature variation may be reduced through the use of an enclosure in which the instrument is positioned. The enclosure functions as a low-pass filter to decrease the effects of the temperature variations. However, the requirement for background drift cannot always be met even with an enclosure.

Such instruments typically include a cooling system that circulates water to cool the instrument during operation. The cooling water has a much higher temperature stability than a typical room (e.g., the ambient environment) in which the instrument is positioned. Thus, it is desired to have better coupling of the air within the enclosure and the cooling water by conditioning the air within the enclosure. The basic principle is to implement passive conditioning of the air within the enclosure by mounting heat exchangers, such as a finned tube heat exchanger, within the enclosure (e.g., on inner walls of the enclosure or within the enclosure air). The heat exchangers have a significant surface area in contact with the enclosure air and are coupled to the existing cooling water system. Therefore, an additional thermal coupling is created between the enclosure air and the cooling water system, increasing the efficacy of the enclosure as a low-pass filter by reducing the DC-gain between ambient air temperature and enclosure air temperature.

Stability of the temperature of the air within the enclosure can further be increased by controlling the temperature of the air actively. Active control can be accomplished by adding an inline water heater in the water supply to the heat exchangers. The heater can elevate the water temperature to provide a control margin. A temperature sensor is positioned to detect the enclosure air, and the water temperature can be controlled so that the temperature of the enclosure air is further stabilized.

Increasing the enclosure temperature stability has a positive effect on drift as well as other areas of instrument performance, such as corrector astigmatism, monochromator drift, and coma drift. Additionally, cooling the enclosure air provides the benefit of additional cooling of the microscope. Cooling of the microscope may reduce drift after inserting a sample into the microscope because the cooled microscope is closer in temperature to the sample.

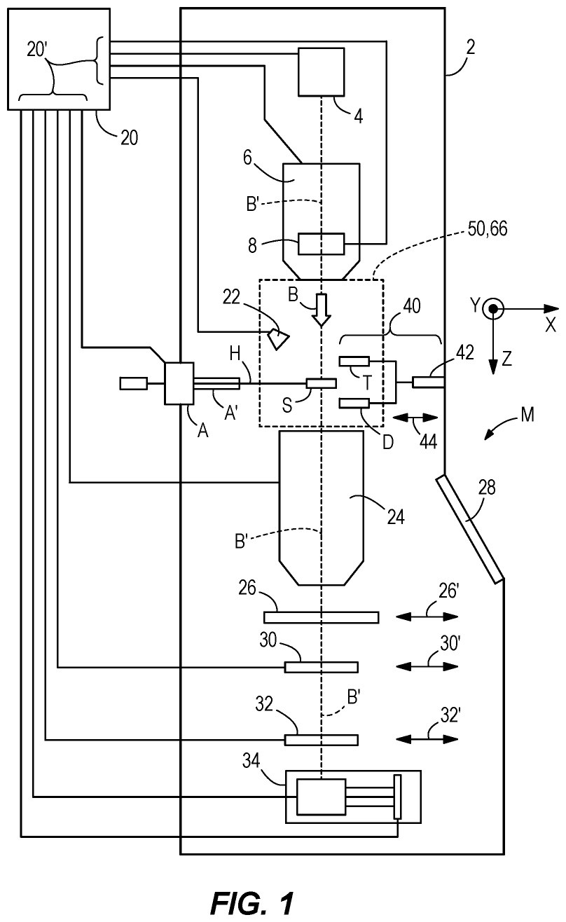

FIG. 1 is a highly schematic depiction of an implementation of a charged particle instrument, illustrated as a microscope M, with which the present disclosure can be implemented; more specifically, it shows an implementation of a transmission-type microscope M, which, in this case, is a TEM/STEM, but may include any other type of electron-based microscope, or an ion-based microscope, a proton-based microscope, or any other type of charged particle microscope, charged particle milling instrument, etc. In FIG. 1, within a vacuum enclosure 2, an electron source 4 (which may generally be referred to herein as a charged particle source) produces a beam B of electrons that propagates along an optical axis B′ (which may be generally referred to herein as a charged particle beam axis), and traverses an optical illuminator 6, serving to direct/focus the electrons (or other charged particles) onto a chosen part of a specimen S (which may, for example, be (locally) thinned/planarized). Also depicted is a deflector 8, which (inter alia) can be used to effect scanning motion of the beam B. Although a transmission-type electron microscope M is described in detail herein, the disclosure applies to any type of charged particle instrument M. The charged particle instrument M may include other types of charged particle microscopes or milling instruments, such as a scanning electron microscope (SEM), a focused ion beam (FIB), etc. Accordingly, the beam B may be an ion beam, a proton beam, or any other type of charged particle.

The specimen S is held on a specimen holder H that can be positioned in multiple degrees of freedom by a positioning device/stage A, which moves a cradle A′ into which the specimen holder H is (removably) affixed; for example, the specimen holder H may comprise a finger that can be moved (inter alia) in the XY plane (see the depicted Cartesian coordinate system; typically, motion parallel to Z and tilt about X/Y will also be possible). Such movement allows different parts of the specimen S to be illuminated/imaged/inspected by the electron beam B traveling along the optical axis B′ (in the Z direction) (and/or allows scanning motion to be performed, as an alternative to beam scanning). If desired, an optional cooling device (not depicted) can be brought into intimate thermal contact with the specimen holder H, so as to maintain it (and the specimen S thereupon) at cryogenic temperatures, for example.

The electron beam B will interact with the specimen S in such a manner as to cause various types of “stimulated” radiation to emanate from the specimen S, including (for example) secondary electrons, backscattered electrons, X-rays and optical radiation (cathodoluminescence). If desired, one or more of these radiation types can be detected with the aid of analysis device 22, which might be a combined scintillator/photomultiplier or EDX (Energy-Dispersive X-Ray Spectroscopy) module, for instance; in such a case, an image could be constructed using basically the same principle as in a scanning electron microscope (SEM). However, alternatively or supplementally, one can study electrons that traverse (pass through) the specimen S, exit/emanate from it and continue to propagate (substantially, though generally with some deflection/scattering) along the optical axis B′. Such a transmitted electron flux enters an imaging system (projection lens) 24, which will generally comprise a variety of electrostatic/magnetic lenses, deflectors, correctors (such as stigmators), etc. In normal (non-scanning) TEM mode, this imaging system 24 can focus the transmitted electron flux onto a fluorescent screen 26, which, if desired, can be retracted/withdrawn (as schematically indicated by arrows 26′) so as to get it out of the way of the optical axis B′. An image (or diffractogram) of (part of) the specimen S will be formed by imaging system 24 on screen 26, and this may be viewed through viewing port 28 located in a suitable part of a wall of the vacuum enclosure 2. In some implementations, the viewing port 28 may be positioned remote from the wall of the vacuum enclosure 2. The retraction mechanism for screen 26 may, for example, be mechanical and/or electrical in nature, and is not depicted here.

As an alternative to viewing an image on screen 26, one can instead make use of the fact that the depth of focus of the electron flux leaving imaging system 24 is generally quite large (e.g. of the order of 1 meter). Consequently, various other types of analysis/sensing devices can be used downstream of screen 26, such as a TEM camera 30, a STEM camera 32, and/or a spectroscopic apparatus 34.

At the TEM camera 30, the electron flux can form a static image (or diffractogram) that can be processed by a controller 20 (which may include a processor, a memory, and inputs and outputs) and displayed on a display device (not depicted), such as a flat panel display, for example. When not required, the TEM camera 30 can be retracted/withdrawn (as schematically indicated by arrows 30′) so as to get it out of the way of the optical axis B′.

An output from the STEM camera 32 can be recorded as a function of (X, Y) scanning position of the beam B on the specimen S, and an image can be constructed that is a “map” of output from the STEM camera 32 as a function of X, Y. The STEM camera 32 can comprise a single pixel with a diameter (of e.g., 20 mm, or any other suitable diameter), as opposed to the matrix of pixels characteristically present in the TEM camera 30. Moreover, the STEM camera 32 will generally have a much higher acquisition rate (e.g., 10⁶ points per second) than the TEM camera 30 (e.g., 10² images per second). Once again, when not required, the STEM camera 32 can be retracted/withdrawn (as schematically indicated by arrows 32′) so as to get it out of the way of the optical axis B′ (although such retraction would not be a necessity in the case of the STEM camera 32 being embodied as a donut-shaped annular dark field camera, for example; in such a camera, a central hole would allow flux passage when the camera was not in use).

As an alternative (or in addition) to imaging using the TEM camera 30 and the STEM camera 32, one can also invoke the spectroscopic apparatus 34, which could be an electron energy loss spectroscopy (EELS) module, for example.

It should be noted that the order/location of items 30, 32 and 34 is not strict, and many possible variations are conceivable. For example, the spectroscopic apparatus 34 can also be integrated into the imaging system 24.

Note that the controller 20 is connected to various illustrated components via control lines (buses) 20′. This controller 20 can provide a variety of functions, such as synchronizing actions, providing setpoints, processing signals, performing calculations, and displaying messages/information on a display device (not depicted). Needless to say, the (schematically depicted) controller 20 may be (partially) inside or outside the vacuum enclosure 2, and may have a unitary or composite structure, as desired.

The skilled artisan will understand that the interior of the vacuum enclosure 2 does not have to be kept at a strict vacuum; for example, in a so-called “Environmental TEM/STEM”, a background atmosphere of a given gas is deliberately introduced/maintained within the vacuum enclosure 2. The skilled artisan will also understand that, in practice, it may be advantageous to confine the volume of the vacuum enclosure 2 so that, where possible, it essentially hugs the optical axis B′, taking the form of a small tube (e.g., of the order of 1 cm in diameter) through which the employed electron beam B passes, but widening out to accommodate structures such as the source 4, the specimen holder H, the screen 26, the TEM camera 30, the STEM camera 32, the spectroscopic apparatus 34, etc.

The microscope M may include a retractable X-ray CT module 40, which can be advanced/withdrawn with the aid of positioning system 42 so as to place it on/remove it from the path of the beam B (see arrow 44). In the particular configuration illustrated here, the module 40 comprises a fork-like frame on which are mounted: a target T and an X-ray detector D. The target T is disposed above the plane of the specimen S. The X-ray detector D is disposed below the plane of the specimen S.

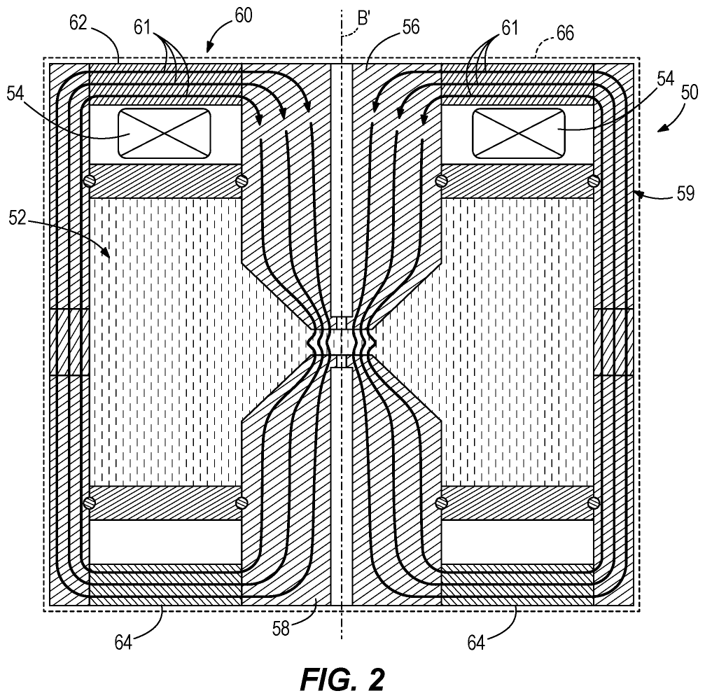

The microscope M also includes a magnetic assembly 50 defining a specimen chamber 52 (which may also be referred to herein as a vacuum chamber 52). The magnetic assembly 50 is disposed between the optical illuminator 6 and the imaging system 24 in the direction of the optical axis B′. (For example, the upper end of the magnetic assembly 50 can be the lower end of the optical illuminator 6 and the lower end of the magnetic assembly 50 can be the beginning of the imaging system 24.) The specimen holder H is received in the specimen chamber 52 in an imaging position (illustrated in FIG. 2) intersecting the optical axis B′. The imaging position is the position in which the specimen S is imaged. The electron beam B intersects the specimen S in the imaging position. The optical axis B′ passes through the magnetic assembly 50. The optical axis B′ may be aligned with a center, or near the center, of the magnetic assembly 50.

In some examples, the magnetic assembly 50 may overlap with either or both of the illuminator 6 and the imaging system 24. For example, one or more lenses of the illuminator may be positioned in the magnetic assembly 50 for directing the charged particle beam towards the specimen.

As best illustrated in FIG. 2, the magnetic assembly 50 includes any number of pieces of magnetic material arranged to shape the magnetic field and guide flux, said piece(s) of magnetic material forming a magnetic yoke 59. For example, as illustrated, the magnetic yoke 59 includes a first pole piece 56, a second pole piece 58, a yoke housing 60, a first yoke plate 62, and a second yoke plate 64, each of which include a magnetic material of relatively high permeability (compared to its surroundings, such as air) that concentrates magnetic field lines 61 into one or more magnetic circuits (closed loops). The magnetic field lines 61 guide the electron beam B (or another charged particle beam) along the optical axis B′ at the specimen S. For example, the magnetic material may include iron, an alloy of nickel-iron, an alloy of cobalt-iron, or any combination thereof. Other magnetic materials may also be employed. The choice of material depends mainly on its maximum magnetic saturation and on its magnetic remanence. Different pieces of the magnetic yoke 59 may be formed from different magnetic materials or the same magnetic materials, as desired. The pieces of the magnetic yoke 59 may be integrated (in any combination) into fewer monolithic parts. For example, the yoke housing 60 may be integrated (e.g., formed as one piece) with one or both of the first yoke plate 62 and the second yoke plate 64; the first pole piece 56 and/or the second pole piece 58 may be integrated with one or both of the first yoke plate 62 and the second yoke plate 64; etc. Any one or more of the pieces of the magnetic yoke 59 may also be separated (in any combination) into more monolithic parts. For example, any of said pieces of the magnetic yoke 59 may be formed from two separate pieces, or more.

The magnetic assembly 50 also includes at least one coil 54. One coil 54 is illustrated in FIG. 2, however any number of coils 54 may be employed, such as two, three, four, or more. In the charged particle microscope M, the charged particles are focused by electric fields or magnetic fields. In the illustrated implementation, a magnetic field is employed. The coil 54 carries windings of wire positioned rotationally symmetrically around the optical axis B′ of the microscope M. The coil 54 is excited by a current, e.g., of several Amperes. As will be described in greater detail herein, cooling of the coil 54 is employed. While excited, the coil 54 creates a strong magnetic field on the optical axis B′ of the microscope M in the axial direction (that is, coaxial with or parallel to the optical axis B′). Since the magnetic field is divergence-free, it inherently has components in the radial direction (that is, perpendicular to the optical axis B′). These radial components grow linearly with the distance to the optical axis B′, and their net effect is a deflection of the charged particles towards the optical axis B′ that scales linearly with the distance of these particles to the optical axis B′. Hence, such a magnetic field acts as a round focusing lens. The focusing strength of a magnetic lens scales with the square of the axial magnetic field and with the length of the axial magnetic field (as measured along the optical axis B′). Therefore, in order to obtain a magnetic lens (i.e., to create lens action), the magnetic field is concentrated in a small region on the optical axis B′ by the magnetic yoke 59 around the coil 54 to guide and focus its magnetic flux to the imaging position on the optical axis B′. The imaging position may only be a few millimeters in length.

Thus, the magnetic assembly 50 at least partially contributes to providing desirable magnetic conditions at the specimen S (and thus at the specimen holder H in the imaging position), sometimes in combination with other components outside of the magnetic assembly 50. The concentrated magnetic field lines 61 in the magnetic material (and particularly the outermost of the concentrated magnetic field lines 61) define a specimen chamber volume 66 in which the specimen holder H is disposed in the imaging position.

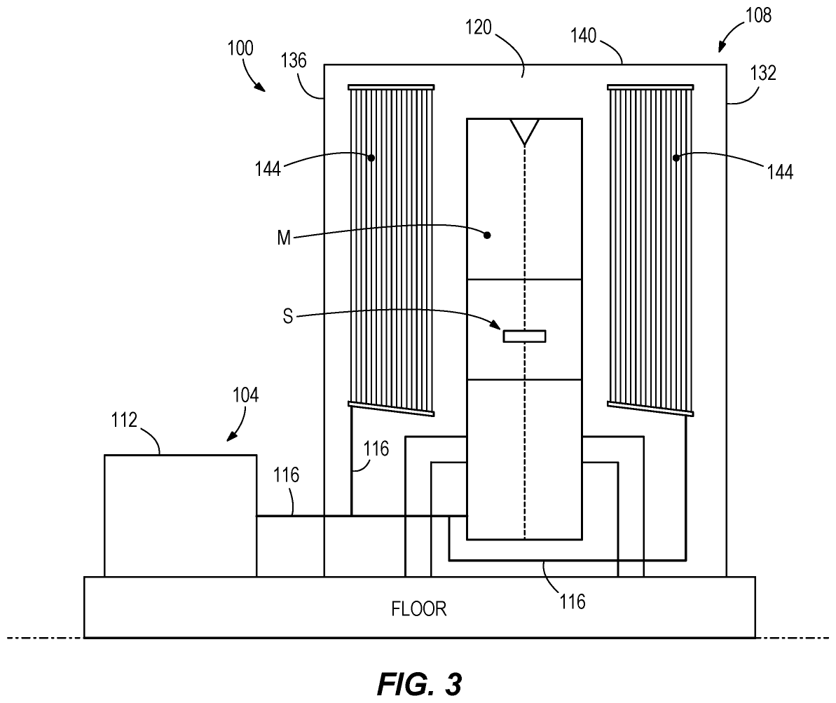

Accuracy of the microscope M described herein may be negatively affected by ambient noise and temperature fluctuations, among other things. Accordingly, the present disclosure provides an instrument system 100 intended to counteract temperature fluctuations and/or ambient noise in a room in which the microscope M is located. FIG. 3 is a schematic illustrating the instrument system 100. The instrument system 100 includes the microscope M (or another charged particle instrument), a thermal conditioning system 104 coupled to the microscope M, and an instrument enclosure 108 in which the microscope M is disposed. The thermal conditioning system 104 provides temperature regulation (e.g., cooling) for the microscope M, and in the illustrated implementation, the thermal conditioning system 104 is operably coupled to the instrument enclosure 108 to provide thermal conditioning to regulate (e.g., stabilize) a temperature of air within the instrument enclosure 108.

Referring to FIGS. 3-5, the thermal conditioning system 104 includes a thermal circuit 116 that circulates a working fluid, such as water or a water-glycol solution, to regulate the temperature of the microscope M and the air within the instrument enclosure 108. The thermal conditioning system 104 includes a temperature regulator, e.g., a chiller 112, that may be disposed outside of the instrument enclosure 108. The chiller 112 is operable to regulate a temperature of the working fluid as the working fluid circulates through the chiller 112. The thermal circuit 116 thermally couples the chiller 112 to the microscope M. The working fluid can be circulated to regulate the temperature of various components of the microscope M. In the illustrated implementation, the thermal circuit 116 is in thermal communication with the magnetic assembly 50, and more particularly to the coil 54, to inhibit over-heating of the magnetic assembly 50 during operation of the microscope M and to provide temperature stability (e.g., minimize drift due to room temperature variations) to the microscope M. In other words, the magnetic assembly 50 is cooled by the thermal conditioning system 104. The thermal circuit 116 may also be in thermal communication with the controller 20 to regulate a temperature (e.g., cool) of the electronic components within the controller 20. The thermal circuit 116 may also be in thermal communication with other components of the microscope M, such as the electron source 4, depending on the need to regulate the temperature of (e.g., cool) said components during operation of the microscope M.

In the illustrated implementation, the chiller 112 may operate under the principles of a vapor compression cycle or any other suitable thermodynamic process configured for removing heat from the thermal circuit 116 and expelling the heat anywhere outside of the enclosure 108. Thus, in one example, the chiller 112 may include a compressor, a condenser, an expansion valve, and an evaporator (not shown) configured in a circuit according to the known principles of vapor compression cycles. In this example, the evaporator (not shown) is in thermal contact with the thermal circuit 116 to cool the working fluid within the thermal circuit 116 as the working fluid circulates through the chiller 112 in thermal communication with the chiller 112. Furthermore, the thermal conditioning system 104 may include a pump (not shown) to circulate the working fluid about the thermal circuit 116. In other examples, the chiller 112 may have any other suitable components for removing heat from the thermal circuit 116 and expelling the heat anywhere outside of the enclosure 108. Thus, the chiller 112 is operable to draw heat out of the working fluid as the working fluid circulates through the chiller 112. In such an implementation, the thermal conditioning system 104 is operable to cool both the microscope M and the air within the enclosure 108. In another implementation, the temperature regulator of the thermal conditioning system 104 may additionally or alternatively include a heater 114. The heater 114 introduces heat to the working fluid to regulate the temperature of the air within the enclosure 108, thereby regulating (e.g., stabilizing) the temperature of the air within the instrument enclosure 108. The heater 114 may be actively controlled (e.g., by the controller 20) to regulate the temperature of the air within the instrument enclosure 108. For example, the heater 114 may introduce heat to the working fluid to raise a temperature of the working fluid. In one example, the temperature of the working fluid may be raised above the temperature of air within the enclosure 108 to heat the air. However, in another example, the temperature of the working fluid may remain below the temperature of the air within the enclosure 108. In such an implementation, heating the working fluid provides a control margin while still utilizing the working fluid to cool the temperature of the air within the enclosure 108. It is therefore possible to control the amount of cooling of the temperature of the air within the enclosure 108 by controlling the amount of heat added to the working fluid.

In the illustrated implementation, the thermal conditioning system 104 is a passive system. Therefore, the chiller 112 is not actively controlled to remove (or introduce) a desired amount of heat from the working fluid. The thermal conditioning system 104 is independent of a temperature of the microscope M or a temperature of air within the instrument enclosure 108. However, in other implementations, the thermal conditioning system 104 may be actively controlled. In such an implementation, the thermal conditioning system 104 may further include one or more temperature sensors to detect temperatures of the air within the instrument enclosure 108, the microscope M, or the working fluid. Such a thermal conditioning system 104 may also include or be in communication with a controller (e.g., the controller 20 or a separate, dedicated controller) to adjust a rate of cooling or set temperature of the chiller 112 to achieve a desired temperature of air within the instrument enclosure 108 or of the microscope M. It should be understood that passive or active control may be applied to thermal conditioning systems that implement refrigeration or heating. Therefore, the thermal conditioning system 104 may include a passively controlled refrigeration system, a passively controlled heating system, an actively controlled refrigeration system, and/or an actively controlled heating system, in any combination.

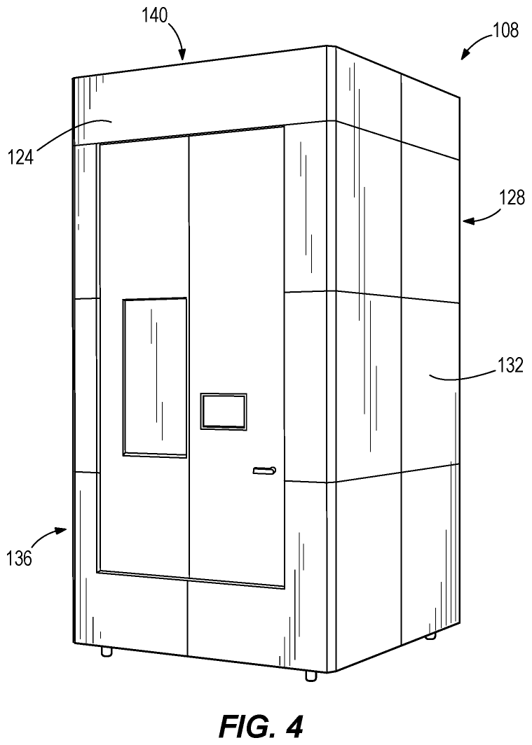

With continued reference to FIGS. 3 and 4, the instrument enclosure 108 defines an interior volume 120 in which the microscope M is disposed. More particularly, the vacuum enclosure 2 of the microscope M is disposed within the interior volume 120. The instrument enclosure 108 includes a front surface 124, a rear surface 128 opposite the front surface 124, a first side surface 132 extending between the front and rear surfaces 124, 128, a second side surface 136 opposite the first side surface 132, and an upper surface 140 coupled to the front, rear, and side surfaces 124, 128, 132, 136. The instrument enclosure 108 of the illustrated implementation has a height of approximately 3.5 meters measured between the upper surface 140 and the floor, and the instrument enclosure defines a floor area that is approximately 1.5 meters by 1.5 meters. In other implementations, the height may be 2.0 meters to 4.0 meters, or may be 3.0 to 4.0 meters, or may be at least 2.0 meters, or may be at least 3.0 meters. The floor area may be at least 1.0 meter by 1.0 meter. Thus, the enclosed volume (i.e., the height multiplied by the floor area) may be between 2.0 m\hat{ }3 and 9.0 m\hat{ }3, or more specifically between 4.0 m\hat{ }3 and 9.0 m\hat{ }3, or more specifically between 5.0 m\hat{ }3 and 9.0 m\hat{ }3, or more specifically between 6.0 m\hat{ }3 and 9.0 m\hat{ }3, or more specifically between 7.0 m\hat{ }3 and 8.0 m\hat{ }3, or may be 9.0 m\hat{ }3 or less. In some implementations, the instrument enclosure 108 includes a lower surface (not shown) opposite the upper surface 104, the lower surface (not shown) defining the floor area. In other implementations, the instrument enclosure 108 may include more or fewer surfaces depending on a desired shape of the instrument enclosure 108. The interior volume 120 of the instrument enclosure 108 is sized to accommodate the microscope M (e.g., the vacuum enclosure 2). In some implementations, it may be desirable for the interior volume 120 to be only slightly larger than the microscope M to decrease an overall footprint of the instrument system 100. Decreasing the volume of the interior volume 120 reduces an amount of air that is regulated by the thermal conditioning system 104 which can lead to greater efficiency in regulating the air temperature. The instrument system 100 (i.e., including the instrument enclosure 108) is positionable within a room in which the microscope M is to be used. In some implementations, the instrument enclosure 108 may be formed of, or include, sound dampening materials, such as. open-cell insulation, foam insulation, rock wool, or glass wool. Therefore, the instrument enclosure 108 operates as a sound attenuating acoustic enclosure and decreases the effects of ambient noise on the microscope M during operation.

In the illustrated implementation, at least one heat exchanger 144 is disposed within the instrument enclosure 108 and in thermal communication with the thermal conditioning system 104 so that the thermal conditioning system 104 can regulate (e.g., cool or heat) the temperature of air within the interior volume 120 of the instrument enclosure 108. In some implementations, the heat exchanger 144 is coupled to the walls of the enclosure 108 to regulate (e.g., cool or heat) the temperature of the enclosure 108. In the illustrated implementation, the heat exchanger 144 is a finned tube heat exchanger. The finned tube heat exchanger 144 of the illustrated implementation may include 34 tubes having a 20 mm diameter and a length of 1800 mm, thus providing a total surface area of 3.8 m². The finned tube heat exchanger 144 may have a convective heat transfer coefficient of 5 W/m²/K and the capability to absorb 114 W. In other implementations, the heat exchanger 144 may be a plate heat exchanger, a plate-fin heat exchanger, or other types of heat exchangers capable of thermal communication with air. The instrument enclosure 108 of the illustrated implementation includes a plurality of heat exchangers 144, though any number of heat exchangers 144 may be employed. The plurality of heat exchangers 144 are supported within the interior volume 120 of the instrument enclosure 108. More particularly, the heat exchangers 144 may be coupled to the side surfaces 132, 136 of the instrument enclosure 108, though any location in thermal contact with air in the interior volume 120 is possible. Each of the plurality of heat exchangers 144 is fluidly coupled to the thermal circuit 116. Thus, circulation of the working fluid in the thermal circuit 116 regulates a temperature of the heat exchangers 144 which, in turn, regulates a temperature of the air within the interior volume 120. The number and/or size of the heat exchangers 144 may be selected based on the amount of cooling desired within the instrument enclosure 108. For example, the instrument enclosure 108 may also include a heat exchanger 144 coupled to the rear surface 128, the upper surface 140, and/or the front surface 124 of the instrument enclosure 108. Furthermore, the instrument enclosure 108 may include a plurality of heat exchangers 144 coupled to a single surface, depending on the size of the heat exchangers.

The above-described thermal conditioning system 104 may utilize the plurality of heat exchangers 144 to cool the air within the instrument enclosure 108. In some implementations, the plurality of heat exchangers 144 may directly cool the instrument enclosure 108, such as the side surfaces 132, 136 of the instrument enclosure 108 (in contrast with only cooling the air within the instrument enclosure 108). In such an implementation, the side surfaces 132, 136 of the instrument enclosure 108 may be in thermal communication with the heat exchangers 144 and/or may be fluidly coupled to the thermal circuit 116 to function as heat exchangers. The effects of variations in room temperature are reduced before the air within the instrument enclosure 108 is affected by directly cooling the side surfaces 132, 136 of the instrument enclosure 108. In yet another implementation, the instrument enclosure 108 may be heated via the heater 114 to allow for regulating the temperature of the air within the instrument enclosure 108. As previously described, the heater 114 may heat the working fluid to allow for controlling the temperature of the working fluid, while maintaining the temperature of the working fluid below the temperature of the air within the instrument enclosure 108. Alternatively, the heater 114 may heat the working fluid to a point that raises the temperature of the air within the instrument enclosure. If the heater 114 is utilized, the heat exchangers 144 may be coupled to the side surfaces 132, 136 to regulate the temperature of the instrument enclosure 108 and/or may be supported so as to be in thermal communication with the air inside of the instrument enclosure 108. Finally, in yet another implementation, the instrument enclosure 108 may be designed such that natural airflow circulates within the instrument enclosure 108 to homogenize the temperature of the air within the instrument enclosure. The instrument enclosure may also include an airflow generator (not shown), such as a fan, to circulate the air within the instrument enclosure 108, thereby homogenizing the temperature of the air.

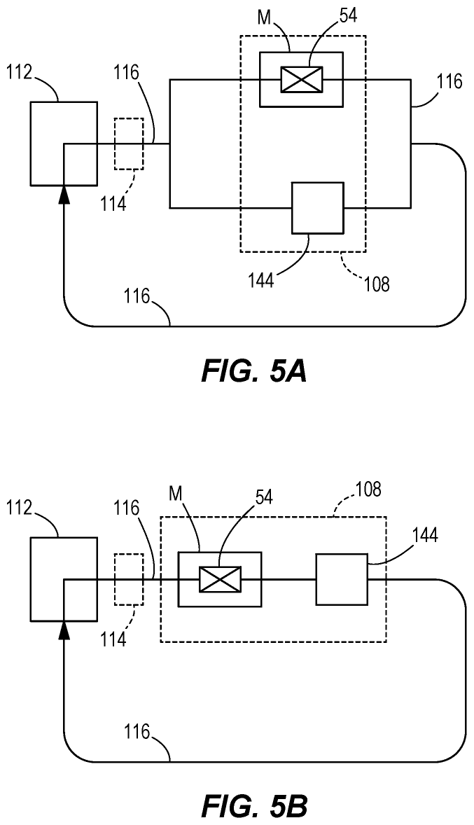

Referring now to FIGS. 5A and 5B, the thermal circuit 116 of the thermal conditioning system 104 will be described in further detail. The thermal circuit 116 thermally couples the chiller 112 to both the microscope M and to the heat exchanger 144 within the instrument enclosure 108. In one implementation, the microscope M and the heat exchanger 144 are disposed in parallel within the thermal circuit 116 (FIG. 5A). In other words, the flow of working fluid is split between the microscope M and the heat exchanger 144 to regulate the temperature of the microscope M and the temperature of the heat exchanger 144 simultaneously. In some implementations, the flow of the working fluid through the microscope M and through the heat exchanger 144 may be controlled independently of each other. In another implementation, the microscope M and the heat exchanger 144 are disposed in series within the thermal circuit 116, such that the temperature of the microscope M is regulated prior to the temperature of the heat exchanger 144 or vice versa (FIG. 5B). The heat exchanger 144 and the microscope M may have any position, relative to one another, within the thermal circuit 116 so long as the heat exchanger 144 and the microscope M are cooled by the same chiller 112. In other implementations, a chiller for the microscope M and a separate chiller for the heat exchanger 144 may be employed.

In operation, the instrument system 100 decreases the effects of temperature fluctuations, such as those within the room in which the microscope M is being used, on the accuracy of the microscope M. Due to the microscope M being located within the instrument enclosure 108, the thermal conditioning system 104 need only regulate the temperature of the relatively small volume of air within the interior volume 120 (e.g., rather than the volume of air within the room, which is much larger). Therefore, requirements for stability of the air temperature within the room itself can be relaxed.

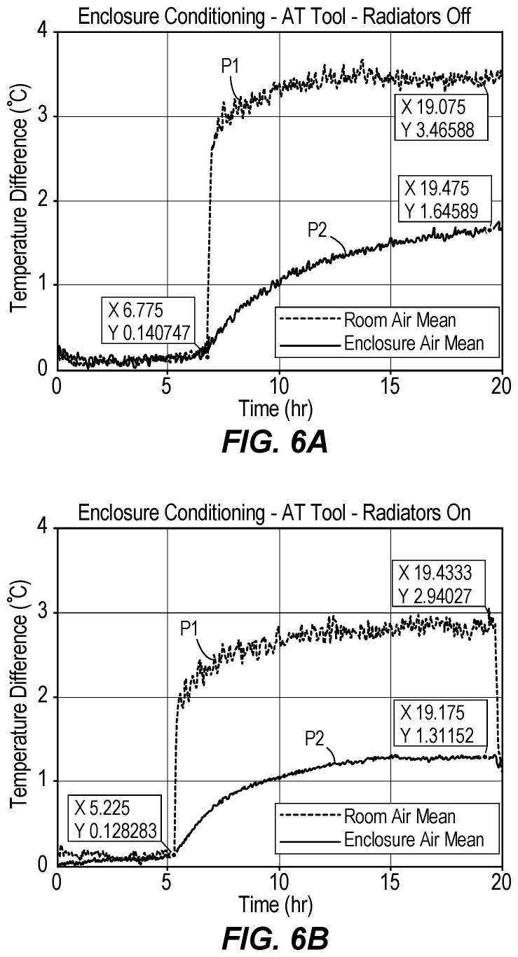

With reference to FIGS. 6A and 6B, cooling or heating the air within the instrument enclosure 108 regulates (e.g., stabilizes) the air surrounding the microscope M so fluctuations in air temperature inside the instrument enclosure 108 are reduced and fluctuations in air temperature outside of the instrument enclosure 108 are less likely to affect the performance of the microscope M. FIG. 6A is a graph of a temperature difference over time without the use of the heat exchangers 144. The graph includes a first plot P1 illustrating room air temperature and a second plot P2 illustrating the air temperature within the instrument enclosure 108. When the room temperature increases, the temperature of the air within the instrument enclosure 108 also increases but remains lower than the room temperature. The second plot P2 of FIG. 6A further illustrates a continuous increase in the temperature of the air within the instrument enclosure 108 over time, which would continuously affect the performance of the microscope M. FIG. 6B is a graph of temperature difference over time with the use of the heat exchangers 144 to regulate (e.g., cool) the air within the instrument enclosure 108. The graph also includes a first plot P1 illustrating room air temperature and a second plot P2 illustrating the air temperature within the instrument enclosure 108. When the room temperature increases, the temperature of the air within the instrument enclosure 108 also increases, but less than without the heat exchangers 144. The air within the instrument enclosure 108 also reaches a steady state when the heat exchangers 144 are utilized, unlike FIG. 6A. When comparing FIGS. 6A and 6B, the use of the heat exchangers 144 illustrates a 7% improvement in DC-gain based on temperature and a 22% improvement in DC-gain based on heat load.

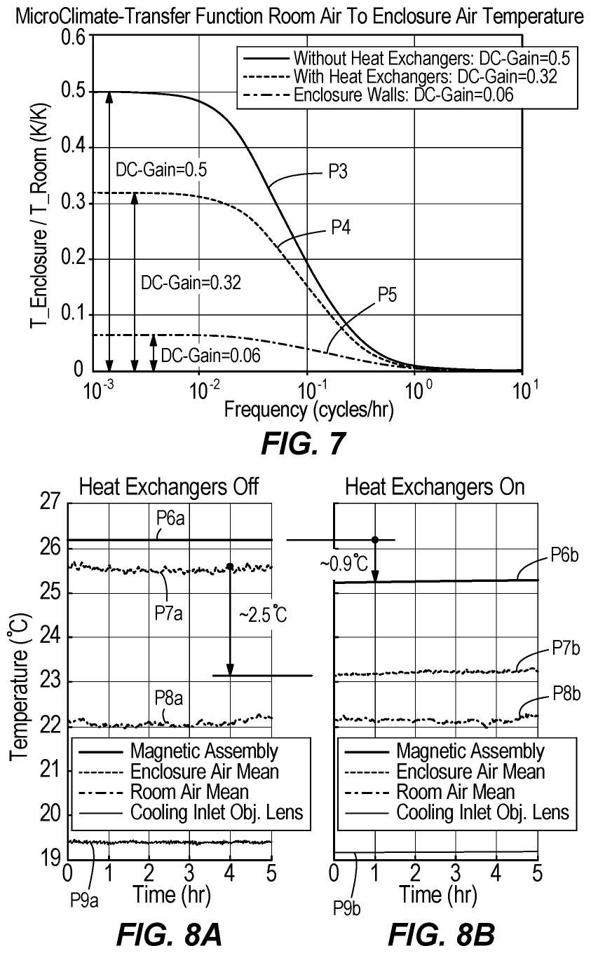

FIG. 7 illustrates a graph of modelled transfer functions between the temperature of air within the room and the air temperature within the instrument enclosure. Plot P3 illustrates the transfer function without use of the heat exchangers 144 and represents a DC-gain of 0.5. Plot P4 illustrates the transfer function with the use of the heat exchangers 144 and represents a DC-gain of 0.32. Plot P5 illustrates the transfer function of the enclosure walls and represents a DC-gain of 0.06. Thus, when considering transfer functions from room air temperature to enclosure air temperature with and without the heat exchangers 144, the DC-gain can be reduced by a factor of 1.6. This means that the air inside the enclosure 108 has become a factor of 1.6 less sensitive to variations in the temperature of air within the room. The modeled best improvement in performance is attained by directly cooling the side surfaces 132, 136 of the instrument enclosure 108, which results in a modeled DC-gain that can be reduced with a factor of 8. When directly cooling the side surfaces 132, 136 of the instrument enclosure 108, the disturbance (i.e., varying room temperature) is reduced prior to the enclosure air being affected by it. Significant improvements in DC-gain can also be obtained using other cooling methods. The system described herein may provide improvements in DC-gain of between 20% and 50%, and more particularly of 36% as tested. The DC-gain can improve by 54% if the area of the heat exchangers 144 is double the area that resulted in the 36% improvement. Improvements in stability based on DC-gain also results in improvements of the accuracy of the microscope M to achieve the background drift specification of 0.5 nm/min maximum. A background drift of the system described herein in various embodiments is 0.35 nm/min in comparison to 0.8 nm/min without the system for 0.4 degree fluctuation in temperature. Regulating may also include reducing the time it takes to reach a steady state air temperature within the instrument enclosure 108 after the microscope M is turned on. In the implementation in which the instrument enclosure 108 includes sound dampening material, the accuracy of the microscope M is further increased because ambient noise is less likely to affect the microscope M.

FIGS. 8A and 8B illustrate measured temperature results of the magnetic assembly 50, the air within the instrument enclosure 108, the room air temperature, and the cooling inlet of the objective lens. FIG. 8A illustrates measurements taken without the use of the heat exchangers 144, and FIG. 8B illustrates measurements taken with the heat exchangers 144. As shown by plots P6a and P6b, the use of the heat exchangers 144 decreases the temperature of the magnetic assembly 50 by approximately 0.9 degrees Celsius. The use of the heat exchangers 144 also decreases the temperature of the air within the instrument enclosure 108 by approximately 2.5 degrees Celsius, as shown by comparing plots Pa and P7b. The temperatures of the room air and cooling inlet of the objective lens, as illustrated by plots P8a/P8b and P9a/P9b, respectively, do not experience significant change.

In some implementations, the instrument enclosure 108 is manufactured and/or sold separately from the microscope M and the thermal conditioning system 104. The instrument enclosure 108 includes the heat exchanger 144 and is retrofittable onto the microscope M and thermal conditioning system 104. Retrofitting may include fluidly coupling the heat exchanger(s) 144 to the thermal circuit 116. After retrofitting, the microscope M is received within the instrument enclosure 108, and the heat exchanger 144 is in thermal communication with the thermal conditioning system 104. In such an implementation, the instrument enclosure 108 may or may not include the sound dampening material. However, the instrument enclosure 108 is thermally coupled to the existing thermal circuit 116 of the microscope.

Thus, the disclosure provides, among other things, a charged particle microscope M having a thermal circuit 116 for cooling the microscope M and stabilizing a temperature of air within an instrument enclosure 108 in which the microscope M is disposed. Various features and advantages of the disclosure are set forth in the following claims.

What is claimed is:

1. A charged particle instrument system comprising:
a charged particle instrument including
a vacuum enclosure, and
a charged particle source disposed within the vacuum enclosure, the charged particle source configured to produce a beam of charged particles that propagate along an axis and interact with a specimen;
an instrument enclosure defining an interior volume, the instrument enclosure being configured to receive at least a portion of the charged particle instrument therein; and
a thermal conditioning system including a temperature regulator in thermal communication with the charged particle instrument to regulate a temperature of the charged particle instrument and in thermal communication with the instrument enclosure to regulate a temperature of air within the interior volume of the instrument enclosure.

2. The charged particle instrument system of claim 1, further comprising an electronic controller configured to control operation of the charged particle instrument, wherein the electronic controller is thermally coupled to the temperature regulator to be cooled by the temperature regulator.

3. The charged particle instrument system of claim 1, wherein the enclosure is an acoustic enclosure configured to decrease the effects of ambient noise on the charged particle instrument.

4. The charged particle instrument system of claim 1, wherein the thermal conditioning system circulates a working fluid between the temperature regulator, a heat exchanger disposed within the instrument enclosure, and the charged particle instrument.

5. The charged particle instrument system of claim 4, wherein the thermal conditioning system includes a controller configured to adjust a temperature of the working fluid based on a desired temperature of air within the instrument enclosure and a detected temperature of air within the enclosure.

6. The charged particle instrument system of claim 4, wherein the working fluid is water.

7. The charged particle instrument system of claim 4, wherein the heat exchanger within the instrument enclosure includes a finned tube heat exchanger.

8. A charged particle instrument system comprising:
a charged particle instrument including:
a vacuum enclosure,
a charged particle source disposed within the vacuum enclosure, the charged particle source configured to produce a beam of charged particles that propagate along an axis and interact with a specimen,
a magnetic assembly disposed within the vacuum enclosure, the magnetic assembly configured to direct the beam of charged particles toward the specimen, and
a controller operably coupled to the charged particle source and to the magnetic assembly;
an instrument enclosure configured to receive at least a portion of the charged particle instrument, the instrument enclosure including a plurality of surfaces defining an enclosed interior volume of the instrument enclosure and configured to decrease an effect of ambient noise on the charged particle instrument; and
a thermal conditioning system in thermal communication with the instrument enclosure and with the magnetic assembly, the thermal conditioning system configured to regulate a temperature of the magnetic assembly and to regulate a temperature of air within the instrument enclosure.

9. The charged particle instrument system of claim 8, wherein the thermal conditioning system includes:
a chiller disposed outside of the instrument enclosure,
a working fluid configured to circulate within the thermal conditioning system, and
a heat exchanger disposed within the instrument enclosure and in thermal communication with the chiller.

10. The charged particle instrument system of claim 9, wherein the chiller is controlled independent of the temperature of air within the instrument enclosure.

11. The charged particle instrument system of claim 9, wherein the heat exchanger disposed within the instrument enclosure includes a finned tube heat exchanger.

12. The charged particle instrument system of claim 9, wherein the heat exchanger is a first heat exchanger of a plurality of heat exchangers.

13. The charged particle instrument system of claim 9, wherein the working fluid includes water.

14. The charged particle instrument system of claim 9, wherein the heat exchanger disposed within the instrument enclosure is disposed outside of the vacuum enclosure.

15. The charged particle instrument system of claim 9, wherein the thermal conditioning system defines a thermal circuit through which the working fluid flows between the chiller, the heat exchanger disposed within the instrument enclosure, and the magnetic assembly, and wherein the heat exchanger disposed within the instrument enclosure and the magnetic assembly are disposed in parallel within the thermal circuit.

16. The charged particle instrument system of claim 9, wherein the instrument is a transmission-type microscope.

17. An instrument enclosure for use with a charged particle instrument, the charged particle instrument having a thermal conditioning system, the instrument enclosure comprising:
a plurality of surfaces defining an interior volume of the instrument enclosure, the interior volume configured to receive at least a portion of the instrument therein; and
a heat exchanger disposed within the interior volume and in thermal communication with air in the interior volume;
wherein the heat exchanger is configured to be fluidly coupled to the thermal conditioning system of the charged particle instrument such that the thermal conditioning system of the charged particle instrument is configured to regulate a temperature of air within the interior volume.

18. The instrument enclosure of claim 17, wherein the heat exchanger includes a finned tube heat exchanger.

19. The instrument enclosure of claim 17, further comprising sound dampening configured to decrease effects of ambient noise on the charged particle instrument.

20. The instrument enclosure of claim 17, wherein the instrument enclosure is retrofittable onto the charged particle instrument.
